(19) United States
(12) Patent Application Publication
(10) Pub. No.: US 2007/0007948 A1
(43) Pub. Date: Jan. 11, 2007

(54) Electrical connection device

(75) Inventors: Ken Kimura, Tokyo (JP); Tsutsumi Kamada, Tokyo (JP)

Correspondence Address: BACON & THOMAS, PLLC, 625 SLATERS LANE, FOURTH FLOOR, ALEXANDRIA, VA, 22314, US

(73) Assignee: Kabushiki Kaisha Nihon Micronics, Tokyo (JP)

(21) Appl. No.: 11/474,424

(22) Filed: Jun. 26, 2006

(30) Foreign Application Priority Data
Jul. 5, 2005 (JP) 2005-196428

(51) Int. Cl. G01R 31/28

(52) U.S. Cl. 324/158.1

(57) ABSTRACT

Inspection is performed without applying an excessive pressure to an inspection object to thereby resolve inspection failure caused by excessive pressure application. An electrical connection device electrically connects a signal wiring formed on a wiring board to an electrode part of the inspection object. A contact is provided which electrically connects together the electrode part of the inspection object and the signal wiring of the wiring board. The contact includes: an electrode abutting part that abuts the electrode part located on a lower portion of the inspection object, a wiring abutting part that abuts the signal wiring, an elastic body support part that fits with the elastic body to elastically support the entire contact, and a release lever part that is pressed to thereby rotate the entire contact whereby the abutting between the electrode part of the inspection object and the electrode abutting part is released. The release lever part is pressed down and released by the cover that moves up and down.

### CROSS-REFERENCE TO RELATED APPLICATION

This application claims, under 35 USC 119, priority of Japanese Application No. 2005-196428 filed Jul. 5, 2005.

### BACKGROUND OF THE INVENTION

1. Field of the Invention

The present invention relates to an electrical connection device for use in inspecting of an inspection object, such as an IC device, an integrated circuit, a liquid crystal display panel, or the like.

2. Description of the Background Art

Disclosed in Japanese Patent Laid-open No. 5-299483 is a connection device, such as an IC chip or the like, for electrical property inspecting. This connection device uses a connecting terminal that is bent into a C-shape. Inspection is performed with this C-shaped connecting terminal abutting an electrode of the IC chip or the like.

In this case, a connection between the C-shaped connecting terminal and the electrode of the IC chip or the like is achieved by pressing the C-shaped connecting terminal against the electrode of the IC chip or the like while in contact with each other.

However, with conventional connection device, for the connection between the C-shaped connecting terminal and the electrode of the IC chip or the like, the IC chip or the like is pressed. This raises a problem with a minute type of IC chip or the like that even just a degree of a pressure applied to the IC chip or the like for the electrical connection may cause property change or circuit breakage.

### SUMMARY OF THE INVENTION

It is an object of the present invention to provide an electrical connection device capable of connection to an electrode by applying the least possible pressure to the inspection object. Thus, the present invention refers to an electrical connection device for electrically connecting a signal wiring formed on a wiring board to the electrode part of the inspection object. The electrical connection device includes a contact that electrically connects the electrode part of the inspection object and the signal wiring on the wiring board. The contact includes: an electrode abutting part that abuts the electrode part located on a lower portion of the inspection object, a wiring abutting part that abuts the signal wiring formed on the wiring board, an elastic body support part that is fitted with and elastically makes contact with an elastic body to thereby support the entire contact, and a release lever part that is pressed to thereby rotate the entire contact whereby the abutting between the electrode part of the inspection object and the electrode abutting part is released.

It is desirable that the electrical connection device further includes a release cover that is so supported as to be movable up and down and pressed down to thereby press down the release lever part of the contact whereby the abutting between the electrode part of the inspection object and the electrode abutting part is released. It is desirable that the contact is provided with a guide surface that guides the inspection object so that the electrode part thereof matches with the electrode abutting part.

### BRIEF DESCRIPTION OF THE DRAWINGS

FIG. 1 is a sectional view showing main parts of an electrical connection device according to an embodiment of the present invention;

FIG. 2 is a perspective view of an inspection object as viewed from the rear side;

FIG. 3 is a sectional view showing the electrical connection device according to the embodiment of the present invention;

FIG. 4 is a plan view showing the electrical connection device according to the embodiment of the present invention;

FIG. 5 is a sectional view showing the electrical connection device according to the embodiment of the present invention, taken along an arrow line A-A of FIG. 4; and

FIG. 6 is a plan view showing a base of the electrical connection device according to the embodiment of the present invention.

### DETAILED DESCRIPTION OF THE PREFERRED EMBODIMENTS

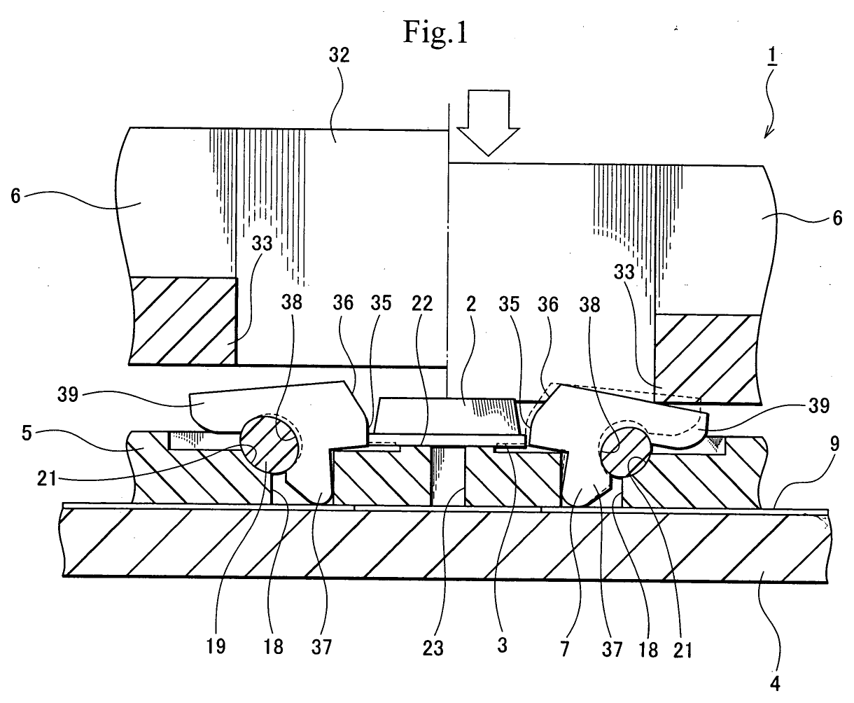

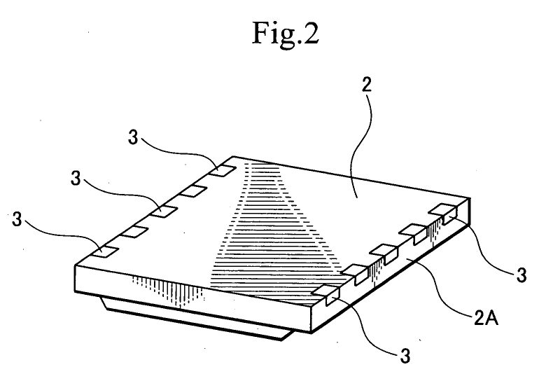

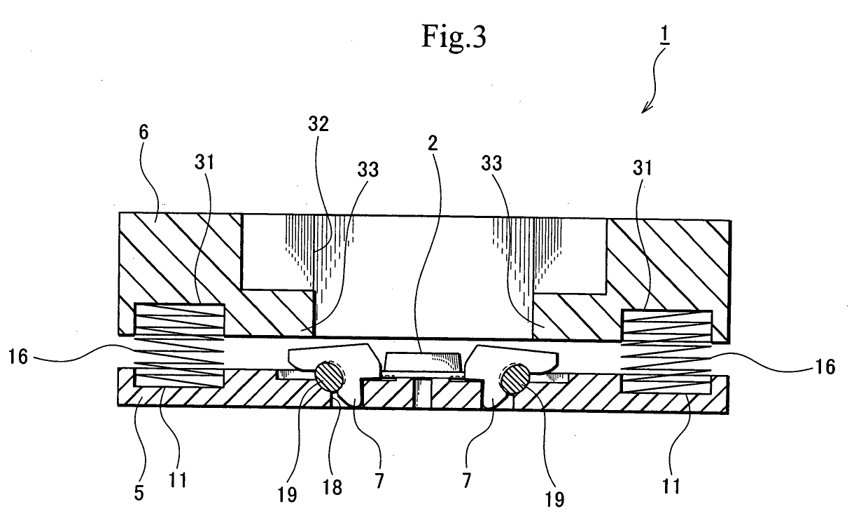

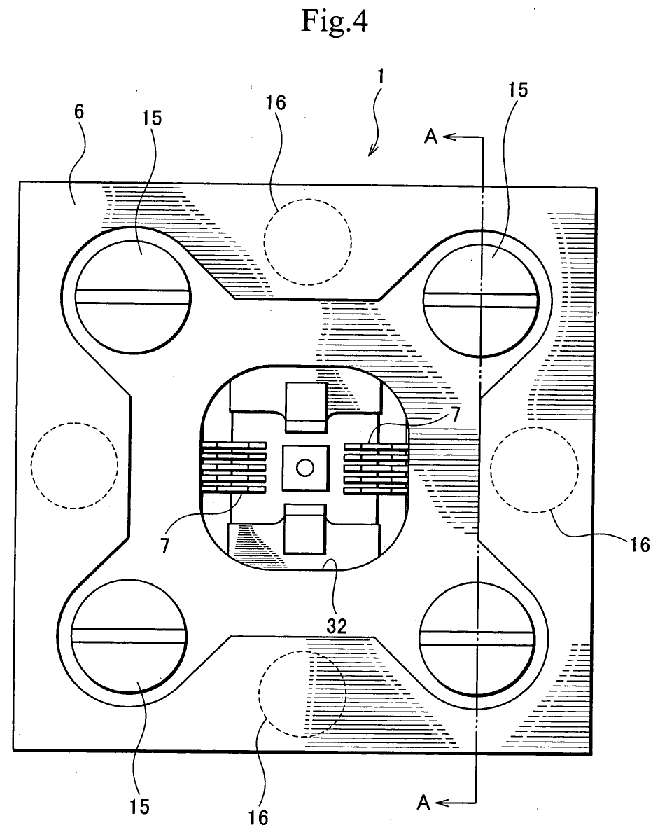

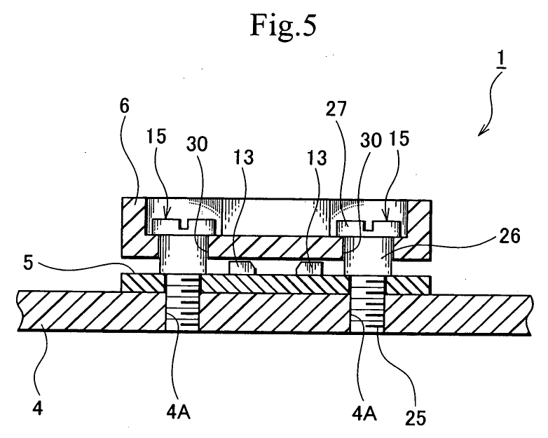

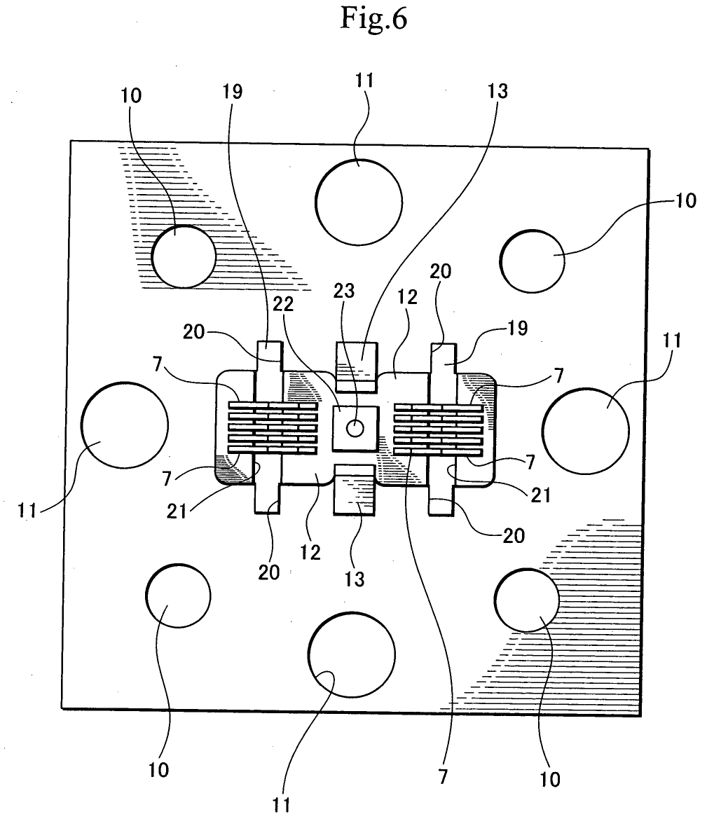

Hereinafter, an electrical connection device according to an embodiment of the present invention will be described referring to the accompanying drawings. FIG. 1 is a sectional view showing main parts of the electrical connection device according to the embodiment of the present invention, FIG. 2 is a perspective view of an inspection object as viewed from the rear side, FIG. 3 is a sectional view showing the electrical connection device, FIG. 4 is a plan view showing the electrical connection device, FIG. 5 is a sectional view showing the electrical connection device taken along an arrow line A-A of FIG. 4, and FIG. 6 is a plan view showing a base of the electrical connection device.

The electrical connection device 1 shown in FIG. 1 is used as an auxiliary device for inspecting of an inspection object 2. The inspection object 2 is the one, such as an IC device, a liquid crystal display panel, or the like, which requires power distribution of an inspection signal. FIGS. 1 and 2 each show one example of the inspection object 2. This inspection object 2 is so configured as to be formed into a square trapezoidal shape and include a flange part 2A therebelow. The flange part 2A of this inspection object 2 is provided with electrode parts 3 for signal input and output. A plurality of electrode parts 3 are arranged in parallel.

The electrical connection device 1 is mainly composed of, as shown in FIGS. 1, 3 to 5, a wiring board 4, a base 5, a cover 6, and contacts 7.

The wiring board 4 is a conductive part for transferring an inspection electrical signal to the inspection object 2 via the contacts 7. The wiring board 4 is formed of an electrical insulation material. On one surface of this wiring board 4, a signal wiring 9 is formed by printed wiring technology. The signal wiring 9 is formed into a pattern in accordance with the position at which the contacts 7 are disposed. With this signal wiring 9, the base end parts of the contacts 7 are brought into electrical contact.

The base 5 is formed into a thick-walled square plate-like shape as shown in FIGS. 1, 3, and 6. The base 5 is composed of screw holes 10, spring seats 11, a contact storage recessed part 12, and device guides 13.

The screw hole 10 is a hole for passing therethrough a fixing screw 15 that fixes the base 5 to the wiring board 4. Four screw holes 10 are provided near the four corners of the base 5. The spring seat 11 is a recessed part for supporting the end part of a compression spring 16 for permitting the cover 6 to elastically approach and separate from the base 5. This spring seat 11 is provided at the middle position between the two adjacent screw holes 10, and is configured to slidably support the cover 6 while maintaining favorable overall balance. How the cover 6 is supported by the fixing screw 15 will be described later.

The contact storage recessed part 12 is a recessed part for rotatably supporting the contacts 7. The contact storage recessed part 12 is so configured as to support the five contacts 7 each disposed on the right and the left thereof. Each contact 7 is disposed in accordance with the position of the electrode part 3 of the inspection object 2. Then, in accordance with the position of the contact 7, a slot 18 is provided. The slot 18 communicates the upper side surface of the contact storage recessed part 12 to the signal wiring 9 on the wiring board 4. Accordingly, the contact 7 makes contact with the signal wiring 9, when inserted into the slot 18.

To the contact storage recessed part 12, two elastic bodies 19 are attached. The elastic body 19 is composed of an elastic, columnar synthetic resin. Each elastic body 19 is disposed in such a direction as to extend across all the five contacts 7 disposed. The both end parts of each elastic body 19 are fitted with and are thereby fixed to elastic body support parts 20 provided in the edge parts of the contact storage recessed part 12. In the contact storage recessed part 12, elastic body fit parts 21 are provided which are each formed into a hemicycle, groove-like shape. This elastic body fit part 21 is disposed so that the center of the elastic body 19 with which the elastic body fit part 21 fits is located around the edge part of the slot 18.

At the central position of the contact storage recessed part 12, an inspection object mounting base 22 is provided. The inspection object mounting base 22 is square-shaped and is so formed as to be slightly ridged. The central part of the inspection object mounting base 22 is provided with a venting hole 23. With the inspection object 2 mounted on the inspection object mounting base 22, the electrode part 3 is likely to protrude from the inspection object mounting base 22 to make contact with the contact 7.

The device guide 13 is a member for guiding the inspection object 2 to mount the inspection object 2 onto the inspection object mounting base 22. The device guides 13 have an inclined surface, and are provided respectively on the both sides in the arrangement direction of the contacts 7 with the inspection object mounting base 22 sandwiched therebetween. The inspection object 2 is guided by the inclined surface of the device guide 13 to be mounted onto the inspection object mounting base 22.

The fixing screw 15 is composed of, as shown in FIG. 5, a screw part 25, a guide part 26 and a screw head part 27. The screw part 25 is a portion which is screwed into and thereby fixed into a screw hole 4A provided in the wiring board 4. Screwing the screw part 25 into the screw hole 4A causes the edge part of the guide part 26 having a larger diameter than the screw part 25 to abut the base 5 to thereby fix the base 5 to the wiring board 4 side. The guide part 26 is a portion that slidably supports the cover 6. A guide hole 30 of the cover 6 fits with the guide part 26 whereby the cover 6 is slidably supported. The screw head part 27 serves as a stopper that prevents the cover 6 from dropping off from the guide part 26.

The compression spring 16 is a spring for elastically supporting the cover 6, as shown in FIG. 3. As for this compression spring 16, the base end part thereof fits with the spring seat 11 of the base 5 and the leading end part thereof fits with a spring seat 31 of the cover 6. By the compression spring 16, the cover 6 is supported in such a manner as to be capable of approaching and separating from the base 5. Accordingly, the cover 6, when pressed down, is caused to approach the base 5, as shown in FIG. 1 from the state on the left to the state on the right, to thereby rotate the contact 7, whereby the pressing force of the contact 7 against the electrode part 3 of the inspection object 2 is released.

The cover 6 is a member for releasing the pressing force of the contact 7 against the electrode part 3 of the inspection object 2, as shown in FIGS. 1, and 3 to 5. Provided near the four corners of the cover 6 are the guide holes 30 to be slidably fitted with the respective guide parts 26 of the fixing screws 15. The insertion of the guide part 26 of the fixing screw 15 into the guide hole 30 slidably supports the cover 6 and also prevents the cover 6 from dropping off at the screw head part 27 of the fixing screw 15. On the rear surface of the cover 6, the spring seats 31 are provided. The spring seat 31 is a recessed part for supporting the end part of the compression spring 16 that permits the cover 6 to elastically approach and separate from the base 5. This spring seat 31 is provided at the middle position between the two adjacent guide holes 30, and slidably supports the cover 6 while maintaining favorable overall balance. In the center of the cover 6, a take in-and-out opening 32 for the inspection object 2 is provided. Further, each edge part of the take in-and-out opening 32 serves as a pressing part 33 for a release lever part 39 of the contact 7. Accordingly, pressing down the cover 6 rotates the contact 7 (rotates into the state of the contact 7 indicated by a solid line on the right of FIG. 1), whereby the abutting part 35 of the contact 7 against the electrode part 3 of the inspection object 2 is released, that is, a released state is provided. In this released state, the inspection object 2 is taken in and taken out.

The contact 7 is a member for electrically connecting the electrode part 3 of the inspection object 2 and the signal wiring 9 on the wiring board 4, as shown in FIGS. 1, 3, and 6. This contact 7 is formed, by using a conductive plate material, into a substantially T overall shape, and has an electrode abutting part 35 and the release lever part 39 disposed respectively on the both sides thereof and a wiring abutting part 37 disposed on the bottom end thereof. More specifically, the contact 7 is composed of the electrode abutting part 35, a guide surface 36, the wiring abutting part 37, an elastic body support part 38, and the release lever part 39.

The electrode abutting part 35 is a portion that directly abuts the electrode part 3 located on the lower portion of the inspection object 2. The electrode abutting part 35 is designed so that an abutting surface thereof with the electrode part 3 is oriented substantially perpendicular when the inspection object 2 is attached. A detailed angle of this abutting surface is specified in accordance with the type of the inspection object 2. In the example of the present embodiment, the abutting surface is so oriented as to be slightly inclined with respect to the perpendicular orientation so that the bottom part of the abutting surface protrudes toward the electrode part 3 side. When the inspection object 2 is mounted on the inspection object mounting base 22, a space is provided at the lower side of the electrode part 3. Therefore, the electrode abutting part 35 abutting with the electrode part 3 of the inspection object 2 may be formed in accordance with the shape of the electrode part 3. More specifically, the electrode abutting part 35 may be formed into an L shape, thus extending around the lower side of the electrode part 3 to make electrical contact therewith. The shape of the electrode abutting part 35 is not limited to an L shape; therefore, a lower side contact part may be provided which extends from the bottom part of the electrode abutting part 35 to the lower side of the electrode part 3 and then extends around the lower side of the electrode part 3 to make contact therewith.

The guide surface 36 is a slant surface for guiding the inspection object 2 to mount the inspection object 2 onto the inspection object mounting base 22. The guide surface 36 is composed of an inclined surface formed continuously to the upper side of the electrode abutting part 35. As a result, the inspection object 2 is mounted on the inspection object mounting base 22 by being guided by the guide surfaces 36 of the contacts 7 and the device guides 13, which are so disposed as to face each other with the inspection object mounting base 22 sandwiched therebetween.

The wiring abutting part 37 is a portion for abutting the signal wiring 9 formed on the wiring board 4. The wiring abutting part 37 abuts the signal wiring 9 to be thereby electrically connected therewith. The leading end part of the wiring abutting part 37 is so formed as to be curved into a substantially circular arc, so that the state in which the wiring abutting part 37 is in contact with the signal wiring 9 may be maintained even when the wiring abutting part 37 slightly rotates.

The elastic body support part 38 is a portion for elastically supporting the entire contact 7. That is, the elastic body support part 38, through its fit with and thus elastic contact with the elastic body 19, elastically supports the entire contact 7. The elastic body support part 38 is so formed as to be notched into a circular arc in accordance with the columnar elastic body 19. The elastic body 19 fits with this elastic body support part 38 shaped into a circular arc to thereby elastically support the contact 7. More specifically, the release lever parts 39 are pressed down by the cover 6, and then the opposing electrode abutting parts 35 of the contacts 7 on the both sides are put into the released state in which they are so pressed as to be widen horizontally (state in which the elastic bodies 19 are so pressed as to shrink), in which state the inspection object 2 is attached. Thus, the electrode abutting parts 35 are pressed against the electrode part 3 by a repulsive force of the elastic bodies 19, and also the portions of the elastic body support parts 38 extending around the lower sides of the elastic bodies 19 are pressed by the repulsive force of the elastic bodies 19 whereby the wiring abutting parts 37 are pressed against the signal wiring 9.

The release lever part 39 is a member for, by being itself pressed down, rotating the contact 7 to thereby widen the space between the opposing electrode abutting parts 35 of the contacts 7 on the both sides so that the inspection object 2 can easily be attached therein. The release lever part 39 is also a member for releasing the abutting between the electrode part 3 of the inspection object 2 and the electrode abutting part 35. The release lever part 39 is provided on the side opposite to the electrode abutting part 35 with the elastic body support part 38 sandwiched therebetween. Pressing down the release lever part 39 by the pressing part 33 of the take in-and-out opening 32 of the cover 6 causes the contact 7 to rotate (rotating from the state indicated by the broken line to the state indicated by the solid line as shown in the contact 7 on the right side of FIG. 1) whereby the abutting between the electrode part 3 and the electrode abutting part 35 is released. In this case, the wiring abutting part 37 abuts the inner side surface of the slot 18 and thus serves as a supporting point, thereby causing the contact 7 to rotate so as to separate the electrode abutting part 35 from the electrode part 3.

[Operation]

The electrical connection device 1 configured as described above operates in the following manner.

First, the cover 6 is pressed down, whereby the cover 6 moves down from the standby state in which the cover 6 is shifted upward by the compression spring 16 with the pressing part 33 pressing down the release lever part 39 of the contacts 7. As a result, the contact 7 is put into the released state in which the contact 7 is rotated (state indicated by the solid line on the right side of FIG. 1), and the inspection object 2 is mounted on the inspection object mounting base 22. In this condition, the elastic body 19 is 30 pressed as to shrink, and a force is acting in the direction in which the contact 7 is pressed back by the repulsive force of the elastic body 19.

This operation of pressing down the cover 6 is performed at the time of attaching the inspection object 2. That is, upon manually or automatically inserting the inspection object 2 into the take in-and-out opening 32 of the cover 6 of the electrical connection device 1, the cover 6 is pressed down, thus providing the released state. As a result, the inspection object 2, being guided by the surfaces 36 of the contacts 7 and the device guides 13, has its position accurately adjusted, and then is mounted onto the inspection object mounting base 22 of the base 5, upon which the electrode part 3 of the inspection object 2 matches the electrode abutting part 35 of the contact 7.

Next, the cover 6 is moved up, whereby the contact 7 is pressed toward the inspection object 2 side by the repulsive force of the elastic body 19, whereby the electrode abutting part 35 of the contacts 7 is pressed against the electrode part 3 of the inspection object 2.

Further, the repulsive force of the elastic body 19 acts even on the bottom part of the elastic body support part 38 of the contact 7 so that the wiring abutting part 37 is pressed against the signal wiring 9. In this case, the electrode abutting part 35 and the electrode part 3 are pressed against each other while making slight sliding movement, and also the wiring abutting part 37 and the signal wiring 9 are pressed against each other while making slight sliding movement. This ensures electrical contact between the signal wiring 9 and the wiring abutting part 37 and also between the electrode abutting parts 35 and the electrode part 3.

Next, an electrical signal is transmitted via the signal wiring 9 and the contact 7 and then inspection is performed.

When the inspection ends, the cover 6 is pressed down, whereby the release lever part 39 of the contact 7 is pressed down, thereby putting the contact 7 into the released state so that the electrode part 3 of the inspection object 2 and the electrode abutting part 35 of the contact 7 are separated from each other. As a result, the inspection object 2 is taken out. Next, a new inspection object 2 is inserted to repeat the processing described above.

As described above, inspection is performed by pressing the inspection object 2 from the right and left, which eliminates the need for application of an excessive pressure to the inspection object 2, thereby resolving inspection failure caused by excessive pressure application.

Each of the electrode parts 3 of the inspection object 2 and the electrode abutting part 35 of the contact 7 can easily and reliably be brought into contact with each other, which is electrically stable. This permits an improvement in the reliability of the inspection device.

The released state can easily be provided by pressing down the cover 6, thereby achieving efficient inspection operation on the inspection object 2.

The contact 7 is provided with the electrode abutting part 35 that abuts the electrode part 3 located on the lower portion of the inspection object 2, therefore, the connection of the contact 7 can be achieved by pressing it from the side surface of the inspection object 2. This consequently can prevent property change caused by application of an unnecessary pressure to the inspection object 2.

The release lever part 39 of the contact 7 is pressed down by the cover 6 to release the abutting between the electrode part 3 of the inspection object 2 and the electrode abutting part 35, thus permitting the inspection object 2 to be easily taken out.

Further, by the guide surface of the contact 7 described above, the inspection object 2 described above is guided so that the electrode part 3 thereof matches the electrode abutting part 35 described above, thus permitting the inspection object 2 to be easily attached.

What is claimed is:

1. An electrical connection device for electrically connecting a signal wiring formed on a wiring board to an electrode part of an inspection object, comprising:
a contact that electrically connects together the electrode part of the inspection object and the signal wiring on the wiring board, wherein the contact comprising:
an electrode abutting part that abuts the electrode part located on a lower portion of the inspection object;
a wiring abutting part that abuts the signal wiring formed on the wiring board;
an elastic body support part that is fitted with and elastically makes contact with an elastic body to thereby support the entire contact; and
a release lever part that is pressed to thereby rotate the entire contact, whereby the abutting between the electrode part of the inspection object and the electrode abutting part is released.

2. The electrical connection device according to claim 1, comprising a release cover that is so supported as to be movable up and down and pressed down to thereby press down the release lever part of the contact, whereby the abutting between the electrode part of the inspection object and the electrode abutting part is released.

3. The electrical connection device according to claim 1,
wherein the contact is provided with a guide surface that guides the inspection object so that the electrode part thereof matches the electrode abutting part.

4. The electrical connection device according to claim 2,
wherein the contact is provided with the guide surface that guides the inspection object so that the electrode part thereof matches the electrode abutting part.
